(19) United States
(12) Patent Application Publication
(10) Pub. No.: US 2026/0206174 A1
(43) Pub. Date: Jul. 16, 2026

(54) Server Information Handling System Fan System

(71) Applicant: Dell Products L.P., Round Rock, TX (US)

(72) Inventors: MingHsueh Tsai, Linkou (TW); Eduardo Escamilla, Round Rock, TX (US)

(21) Appl. No.: 19/019,842

(22) Filed: Jan. 14, 2025

(51) Int. Cl. H05K 7/20; F04D 29/40; F04D 29/70

(52) U.S. Cl. CPC H05K 7/20172; F04D 29/403; F04D 29/703; H05K 7/20736

(57) ABSTRACT

A fan system for an information handling system. The fan system includes a fan device; and a fan grill component, the fan grill component including a fan grill housing; a fan grill portion attached to the fan grill housing; and, a fan carrier latch mechanism mounted to the fan grill housing, the fan carrier latch mechanism being mounted to be positioned in front of a hub portion of a fan device of the fan system.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server type information handling system with a fan system.

In one embodiment, the invention relates to a fan grill component for a fan system for use with an information handling system, comprising: a fan grill housing; a fan grill portion attached to the fan grill housing; and, a fan carrier latch mechanism mounted to the fan grill housing, the fan carrier latch mechanism being mounted to be positioned in front of a hub portion of a fan device of the fan system.

In another embodiment, the invention relates to a fan system for an information handling system comprising: a fan device; and a fan grill component, the fan grill component comprising: a fan grill housing; a fan grill portion attached to the fan grill housing; and, a fan carrier latch mechanism mounted to the fan grill housing, the fan carrier latch mechanism being mounted to be positioned in front of a hub portion of a fan device of the fan system.

In another embodiment, the invention relates to a system comprising: a chassis; a processor contained within the chassis; a data bus coupled to the processor; a plurality of components contained within the chassis; and, a fan system for cooling the plurality of components, the fan system comprising a fan device; and a fan grill component, the fan grill component comprising: a fan grill housing; a fan grill portion attached to the fan grill housing; and, a fan carrier latch mechanism mounted to the fan grill housing, the fan carrier latch mechanism being mounted to be positioned in front of a hub portion of a fan device of the fan system.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a generalized perspective view of fan system environment.

FIG. 5 shows a front view of a fan device.

FIGS. 6A, 6B, 6C, 6D, 6E, 6F, 6G, and 6H, generally referred to as FIG. 6, show a plurality of views of fan grill component of a fan system.

### DETAILED DESCRIPTION

Various aspects of the present disclosure include an appreciation that server type information handling system structural designs are becoming increasingly large as a function of growing component size and increasing heat loads within the system. Various aspects of the present disclosure include an appreciation that it is known to provide information handling systems with a plurality of components. Various aspects of the present disclosure include an appreciation that graphics processing unit (GPU) modules (often referred to as accelerator add in cards (AICs) are examples of components that are often included within an information handling system. Various aspects of the present disclosure include an appreciation that it may be desirable to provide an information handling system with an array of components. Various aspects of the present disclosure include an appreciation that it may be desirable to install an array of GPU modules within an information handling system. Various aspects of the present disclosure include an appreciation that arrays of components often require additional structural support.

Various aspects of the present disclosure include an appreciation that GPU modules are often configured to conform to form factor standards. Various aspects of the present disclosure include an appreciation that the card electromechanical (CEM) form factor standard is one such form factor standard. Various aspects of the disclosure include an appreciation that it is known to provide information handling systems with baseboard systems such as peripheral component interconnect express (PCIe) type baseboard systems.

Various aspects of the present disclosure include an appreciation that cooling an array of components can often require careful airflow management. Various aspects of the present disclosure include an appreciation that cooling an array of components can often present a number of information handling system design challenges. These design challenges are especially present in systems which are designed with a plurality of components such as a plurality of GPUs. These design challenges are also especially present in systems which are designed to support artificial intelligence (AI) workloads.

Various aspects of the present disclosure include an appreciation that it is desirable to minimize airflow losses to maximize performance and manage power consumption. Various aspects of the present disclosure include an appreciation that the area in front of the fan blades of a fan device is often the area of the fan system where the highest velocity airflow is generated. Various aspects of the disclosure include an appreciation that an aspect of fan system design that contributes to airflow loss is the fan grill component.

Varius aspects of the present disclosure include an appreciation that fan grill components can require latches to provide access to the fan device of the fan system. Various aspects of the present disclosure include an appreciation that latch elements often require a latch touchpoint to facilitate manipulation of the latch element. Various aspects of the present disclosure include an appreciation that latches of known fan grill components often partially obstruct fan blades of the fan device of the fan system. Various aspects of the present disclosure include an appreciation that latches of known fan grill components have been positioned on a side portion of the fan grill component or on a top portion of a fan grill component. Various aspects of the present disclosure include an appreciation that latches positioned on a side portion of the fan grill component or on a top portion of a fan grill component can partially cover a front of a fan blade portion of the fan device. Various aspects of the disclosure include an appreciation that partially covering a front of a fan blade portion of the fan device can contribute to airflow loss.

A system and method are disclosed for providing a server type information handling system with a fan system. In certain embodiments, the fan system includes a plurality of fans. In certain embodiments, each of the plurality of fans includes a fan grill component. In certain embodiments, the fan grill component includes an airflow optimized fan carrier latch mechanism. In certain embodiments, the airflow optimized fan carrier latch mechanism is positioned at a hub area of a fan device. Because the hub area of the fan device is the least crucial area for airflow, positioning the fan carrier latch mechanism at the hub area provides a desirable location for the release mechanism. By so positioning the fan carrier latch mechanism, fan blades of the fan device are minimally obstructed by a latch touchpoint of the latch mechanism.

Such an airflow optimized fan carrier latch mechanism advantageously provides a fan system in which the fan blades are minimally obstructed by the fan carrier latch mechanism. Such an airflow optimized fan carrier latch mechanism effectively uses airflow and thus minimizes power consumption by the fan system. Such an airflow optimized fan carrier latch mechanism provides cost savings and improved performance for information handling system.

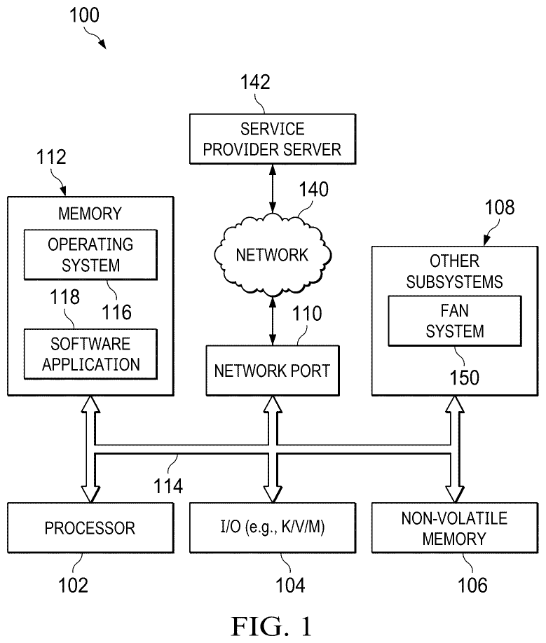

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 include a fan system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the fan system 150 includes a plurality of fans. In certain embodiments, each of the plurality of fans includes a fan device and a fan grill component. In certain embodiments, the fan grill component includes an airflow optimized fan carrier latch mechanism. In certain embodiments, the airflow optimized fan carrier latch mechanism is positioned at a hub area of the fan device. Because the hub area of the fan device is the least crucial area for airflow, positioning the fan carrier latch mechanism at the hub area provides a desirable location for the release mechanism. By so positioning the fan carrier latch mechanism, fan blades of the fan device are minimally obstructed by a latch touchpoint of the latch mechanism.

Such an airflow optimized fan carrier latch mechanism advantageously provides a fan system in which the fan blades are minimally obstructed by the fan carrier latch mechanism. Such an airflow optimized fan carrier latch mechanism effectively uses airflow and thus minimizes power consumption by the fan system. Such an airflow optimized fan carrier latch mechanism provides cost savings and improved performance for information handling system.

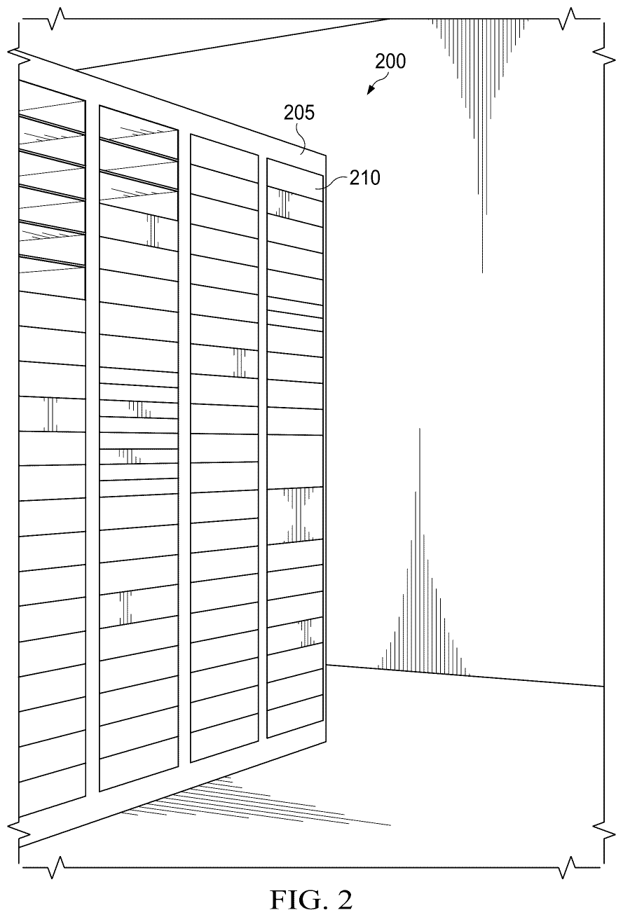

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1 U rack unit, a 2 U rack unit, and a 4 U rack unit. In general, a 1 U rack unit is substantially (i.e., +/−20%) 1.75″ high, a 2 U rack unit is substantially (i.e., +/−20%) 3.5″ high, and a 4 U rack height is substantially (i.e., +/−20%) 7.0″ high.

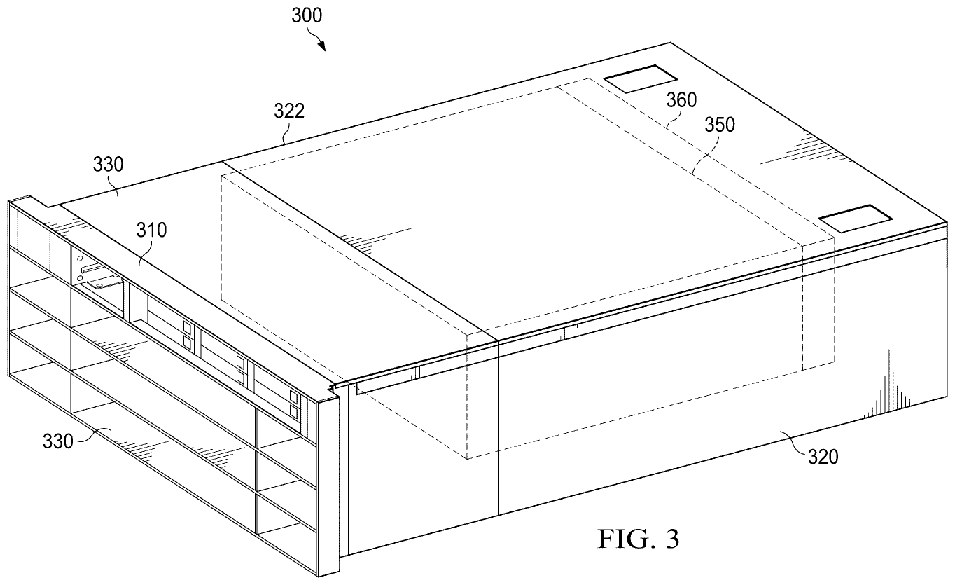

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a component region 350, a fan system 360, or a combination thereof. In certain embodiments, the fan system 360 corresponds to fan system 150.

In certain embodiments, the fan system 360 includes a plurality of fans. In certain embodiments, each of the plurality of fans includes a fan device and a fan grill component. In certain embodiments, the fan grill component includes an airflow optimized fan carrier latch mechanism. In certain embodiments, the airflow optimized fan carrier latch mechanism is positioned at a hub area of the fan device. Because the hub area of the fan device is the least crucial area for airflow, positioning the fan carrier latch mechanism at the hub area provides a desirable location for the release mechanism. By so positioning the fan carrier latch mechanism, fan blades of the fan device are minimally obstructed by a latch touchpoint of the latch mechanism.

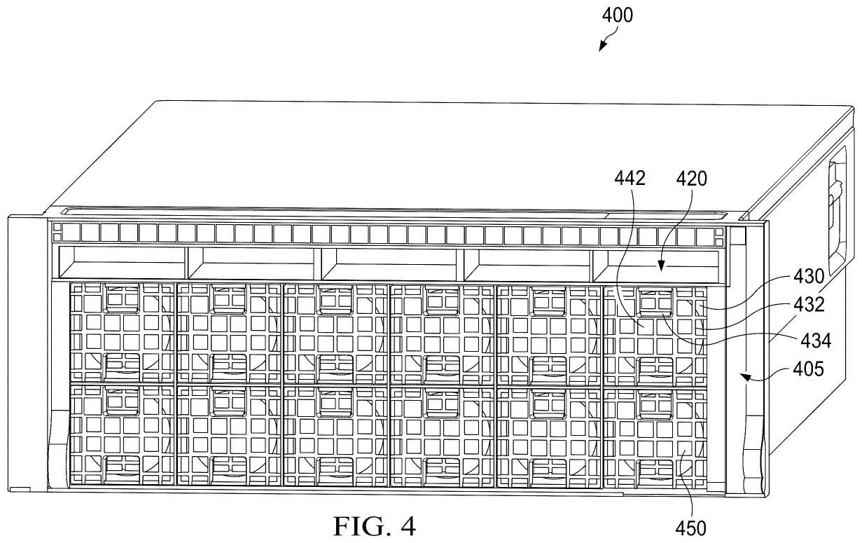

FIG. 4 shows a generalized perspective view of fan system environment 400. In certain embodiments, the fan system environment 400 includes the fan system 405, a component region 410, or a combination thereof. In certain embodiments, the fan system 405 corresponds to fan system 150. In certain embodiments, the component region 410 is cooled by airflow generated by the fan system 405.

As used herein, a component region of an information handling system broadly refers to an area of the information handling system in which a plurality of components are installed along with one or more support functions associated with the plurality of components. In certain embodiments, the one or more support functions include a component system board, a power distribution system, power supply units for powering the plurality of components, etc. In certain embodiments, the plurality of components of the component region are arranged as an array of components. In certain embodiments, the plurality of components of the component region include a plurality of GPU modules. In certain embodiments, the plurality of GPU modules are designed to support artificial intelligence (AI) workloads.

In certain embodiments, the fan system 405 includes a plurality of fans 420. In certain embodiments, each of the plurality of fans 420 includes a fan device 430 and a fan grill component 432. In certain embodiments, the fan grill component 432 includes an airflow optimized fan carrier latch mechanism 440. In certain embodiments, the airflow optimized fan carrier latch mechanism 440 is positioned at a hub area 442 of the fan device 430. Because the hub area of the fan device is the least crucial area for airflow, positioning the fan carrier latch mechanism 440 at the hub area 442 provides a desirable location for the release mechanism. By so positioning the fan carrier latch mechanism, fan blades 450 of the fan device 430 are minimally obstructed by a latch touchpoint of the latch mechanism.

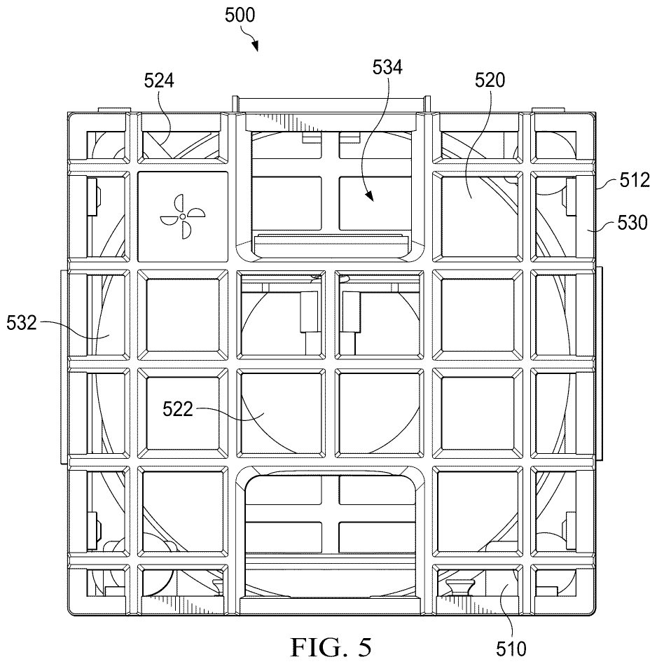

FIG. 5 shows a front view of a fan device 500. In certain embodiments, the fan 500 corresponds to a fan of fan system 150. In certain embodiments, the fan 500 includes a fan device 510, a fan grill component 512, or a combination thereof.

In certain embodiments, the fan device 510 includes a fan blade portion 520, a hub portion 522, a fan housing 524, or a combination thereof. In certain embodiments, the fan blade portion 520 and the hub portion 522 are contained within the fan housing 524. In certain embodiments, the area in front of the fan blade portion 532 is the area of the fan 500 where the highest velocity airflow is generated. In certain embodiments, the fan blade portion 520 is substantially circular. In certain embodiments, the hub portion 522 is substantially circular. In certain embodiments, the fan blade portion 520 includes a plurality of fan blades. In certain embodiments, the plurality of fan blades of the fan blade portion 520 rotate about the hub portion 522.

In certain embodiments, the fan grill component 512 includes a fan grill housing 530, a fan grill portion 532, a fan carrier latch mechanism 534, or a combination thereof. In certain embodiments, the fan grill portion 532 is physically attached to the fan grill housing 530. In certain embodiments, the fan housing 530 and the fan grill portion 532 are constructed from a single piece of material. In certain embodiments, the fan carrier latch mechanism 534 is physically attached to the fan grill housing 530. In certain embodiments, the fan grill housing 530 and the fan carrier latch mechanism 534 are constructed from different pieces of material.

In certain embodiments, the fan carrier latch mechanism 534 is configured as an airflow optimized fan carrier latch mechanism. In certain embodiments, the fan carrier latch mechanism 534 is positioned in front of the hub portion 534 of the fan device 510. Because the hub portion 534 of the fan device 510 is the least crucial area for airflow, positioning the fan carrier latch mechanism 530 in front of the hub portion 534 provides a desirable location for the fan carrier latch mechanism 530. By so positioning the fan carrier latch mechanism 530, fan blades of the fan portion 520 are minimally obstructed by a fan carrier latch mechanism 530.

In certain embodiments, the fan carrier latch mechanism 530 includes a latching portion 540, one or more latch touchpoints 542, or a combination thereof. In certain embodiments, the latching portion 540 is configured to removably attach the fan gill component 512 to the fan device 510. In certain embodiments, the latching portion 540 is configured to removably attach the fan gill component 512 to the fan housing 524 of the fan device 510. In certain embodiments, the one or more latch touchpoint portions 542 include a top latch touchpoint portion and a bottom latch touchpoint portion.

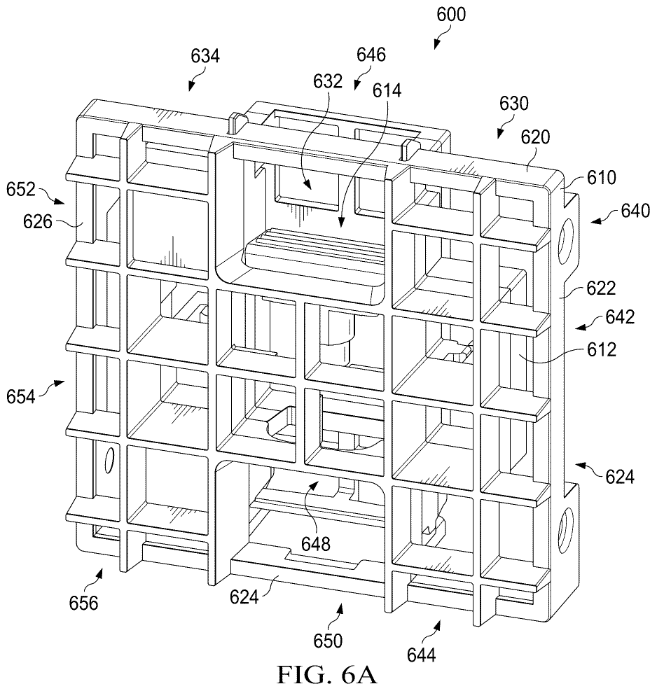

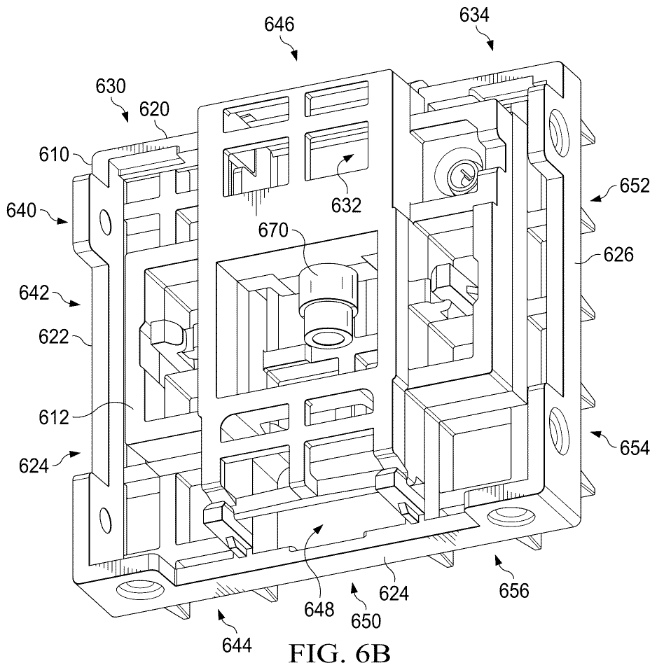

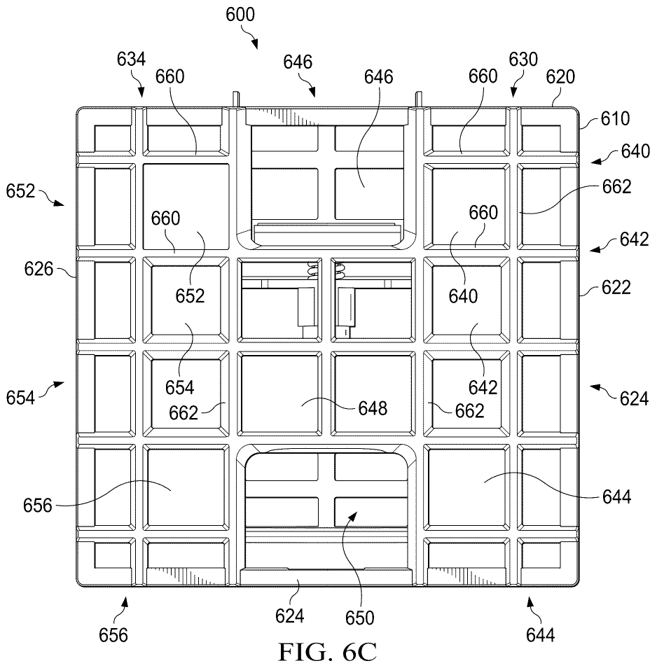

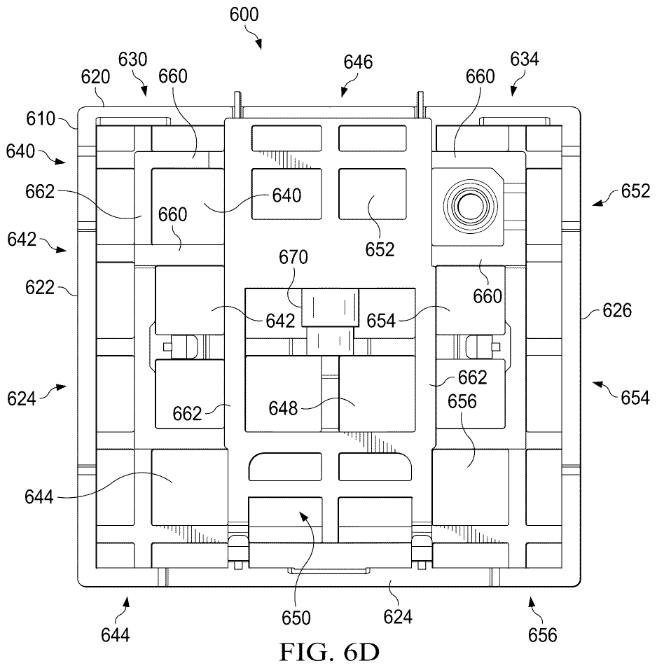

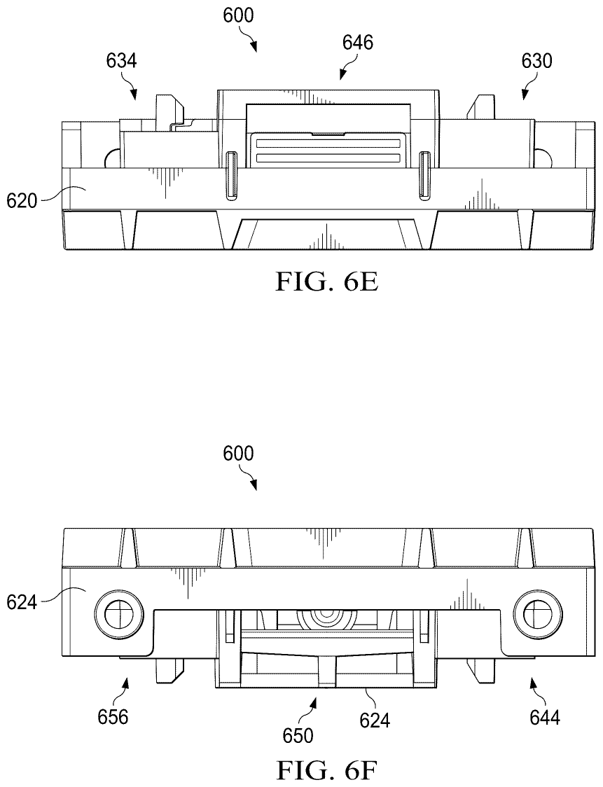

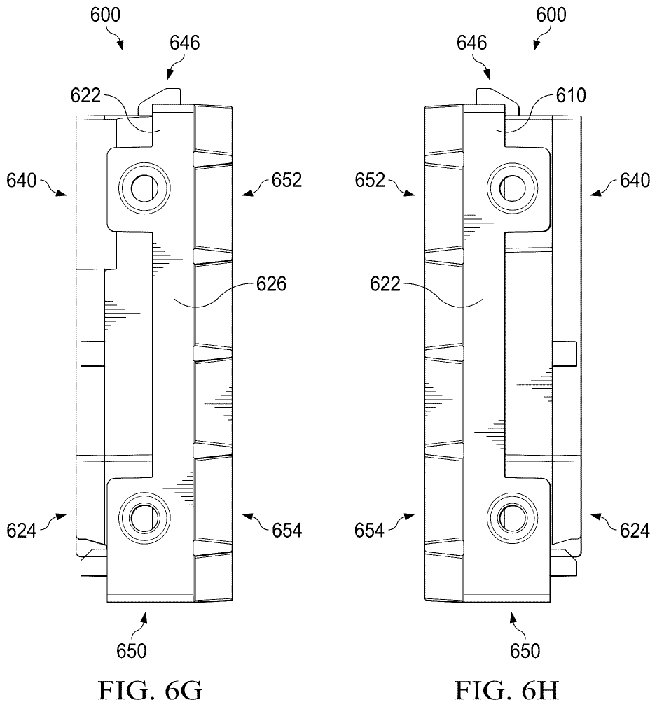

FIGS. 6A, 6B, 6C, 6D, 6E, 6F, 6G, and 6H, generally referred to as FIG. 6, show a plurality of views of fan grill component 600 of a fan system. More specifically, FIG. 6A shows a front perspective view of a fan grill component 600 of a fan system. FIG. 6B shows a rear perspective view of a fan grill component 600 of a fan system. FIG. 6C shows a front view of a fan grill component 600 of a fan system. FIG. 6D shows a rear view of a fan grill component 600 of a fan system. FIG. 6E shows a top view of a fan grill component 600 of a fan system. FIG. 6F shows a bottom view of a fan grill component 600 of a fan system. FIG. 6G shows a left view of a fan grill component 600 of a fan system. FIG. 6H shows a right view of a fan grill component 600 of a fan system. In certain embodiments, the fan grill component 600 corresponds to a fan grill component of fan system 150.

In certain embodiments, the fan grill component 600 includes a fan grill housing 610, a fan grill portion 612, a fan carrier latch mechanism 614, or a combination thereof. In certain embodiments, the fan grill portion 612 is physically attached to the fan grill housing 610. In certain embodiments, the fan housing 610 and the fan grill portion 612 are constructed from a single piece of material. In certain embodiments, the fan carrier latch mechanism 614 is physically mounted to the fan grill housing 610. In certain embodiments, the fan grill housing 610 and the fan carrier latch mechanism 614 are constructed from different pieces of material.

In certain embodiments, the fan grill housing 610 mounts to exterior edges on a fan device housing. In certain embodiments, the fan grill housing 610 includes a top side wall component 620, a bottom side wall component 622, a right side wall component 624, a left side wall component 626, or a combination thereof. In certain embodiments, the top side wall component 620, the bottom side wall component 622, the right side wall component 624, and the left side wall component 626 are constructed from a single piece of material. In certain embodiments, right side wall component 624 extends substantially perpendicularly from the top side wall component 620. In certain embodiments, left side wall component 626 extends substantially perpendicularly from the top side wall component 620. In certain embodiments, the bottom side wall component 622 extends substantially perpendicularly from the right side wall component 624. In certain embodiments, the bottom side wall component 622 extends substantially perpendicularly from the left side wall component 626. In certain embodiments, the top side wall component 620, the bottom side wall component 622, the right side wall component 624, and the left side wall component 626 are substantially square shaped.

In certain embodiments, the fan grill portion 612 includes a first side portion 630, a middle portion 632, a second side portion 634, or a combination thereof. In certain embodiments, the first side portion 630 includes a right, top portion 640, a right, middle portion 642, a right, bottom portion 644, or a combination thereof. In certain embodiments, the middle portion 632 includes a middle, top portion 646, a middle, middle portion 648, a middle, bottom portion 650, or a combination thereof. In certain embodiments, the second side portion 634 includes a left, top portion 652, a left, middle portion 654, a left, bottom portion 656, or a combination thereof.

In certain embodiments, the fan grill portion 612 includes a plurality of horizontal grill elements, 660, a plurality of vertical grill elements 662, or a combination thereof. In certain embodiments, the plurality of horizontal grill elements 660 include horizontal edge grill elements, horizontal interior grill elements, or a combination thereof. In certain embodiments, the plurality of vertical grill elements 662 include vertical edge grill elements, vertical interior grill elements, or a combination thereof.

In certain embodiments, the fan carrier latch mechanism 614 is configured as an airflow optimized fan carrier latch mechanism. In certain embodiments, the fan carrier latch mechanism 614 is positioned in front of a hub portion of the fan device. Because the hub portion of the fan device is the least crucial area for airflow, positioning the fan carrier latch mechanism 610 in front of the hub portion provides a desirable location for the fan carrier latch mechanism 610. By so positioning the fan carrier latch mechanism 610, fan blades of the fan device are minimally obstructed by a fan carrier latch mechanism 610.

In certain embodiments, the fan carrier latch mechanism 610 includes a latching portion 670, one or more latch touchpoints 672, or a combination thereof. In certain embodiments, the latching portion 670 is configured to removably attach the fan gill component 600 to a fan device. In certain embodiments, the latching portion 670 is configured to removably attach the fan gill component 600 to a fan housing. In certain embodiments, the one or more latch touchpoint portions 672 include a top latch touchpoint portion and a bottom latch touchpoint portion. In certain embodiments, the top latch touchpoint portion is configured to actuate the latching portion 670. In certain embodiments, the latching portion 670 is positioned behind the middle, middle portion 652 of the fan grill portion 612.

In certain embodiments, the middle, top portion 646 of the fan grill portion 612 defines a top opening. In certain embodiments, the top opening facilitates access to the top latch touchpoint portion of the latching portion 670. In certain embodiments, the opening is provided by not having horizontal grill elements 660 or vertical grill elements 662 within the middle, top portion 646 of the fan grill portion 612. In certain embodiments, the middle, bottom portion 650 of the fan grill portion 612 defines a bottom opening. In certain embodiments, the bottom opening facilitates access to the bottom latch touchpoint portion of the latching portion 670. In certain embodiments, the opening is provided by not having horizontal grill elements 660 or vertical grill elements 662 within the middle, bottom portion 646 of the fan grill portion 612.

In certain embodiments, the fan carrier latch mechanism 610 includes a top portion 680, a middle portion 682, a bottom portion 684, or a combination thereof. In certain embodiments, the top portion 680 is positioned behind the middle, top portion 646 of the fan grill portion 612. In certain embodiments, the middle portion 682 is positioned behind the middle, middle portion 648 of the fan grill portion 612. In certain embodiments, the bottom portion 684 is positioned behind the middle, bottom portion 650 of the fan grill portion 612.

In certain embodiments, the top portion 680 defines a cavity behind the top opening provided by middle, top portion 646 of the fan grill portion 612. In certain embodiments, a bottom edge of the cavity of the top portion 680 is defined by the top latch touchpoint portion. In certain embodiments, the bottom portion 684 defines a cavity behind the bottom opening provided by middle, bottom portion 650 of the fan grill portion 612. In certain embodiments, a top edge of the cavity of the bottom portion 684 is defined by the bottom latch touchpoint portion.

In certain embodiments, a rear wall of the top portion 680 includes a plurality of horizontal grill elements 690, a plurality of vertical grill elements 692, or a combination thereof. In certain embodiments, a rear wall of the cavity of the top portion 680 includes the plurality of horizontal grill elements 690, the plurality of vertical grill elements 692, or a combination thereof. In certain embodiments, a rear wall of the bottom portion 684 includes a plurality of horizontal grill elements 690, a plurality of vertical grill elements 692, or a combination thereof. In certain embodiments, a rear wall of the cavity of the bottom portion 684 includes the plurality of horizontal grill elements 690, the plurality of vertical grill elements 692, or a combination thereof.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A fan grill component for a fan system for use with an information handling system, comprising:
a fan grill housing;
a fan grill portion attached to the fan grill housing; and,
a fan carrier latch mechanism mounted to the fan grill housing, the fan carrier latch mechanism being mounted to be positioned in front of a hub portion of a fan device of the fan system.

2. The fan grill component of claim 1, wherein:
the fan carrier latch mechanism includes a latching portion, the latching portion being configured to removably attach the fan grill component to the fan device.

3. The fan grill component of claim 2, wherein:
the fan carrier latch mechanism includes a latch touchpoint.

4. The fan grill component of claim 3, wherein:
the fan carrier latch mechanism includes a top portion, a middle portion and a bottom portion;
the fan latch mechanism is contained within the middle portion; and
the latch touchpoint is contained within one of the top portion and the bottom portion.

5. The fan grill component of claim 4, wherein:
the fan grill portion includes a middle portion; and,
the fan carrier latch mechanism is mounted behind the middle portion.

6. The fan grill component of claim 5, wherein:
the middle portion includes a fan grill middle, top portion, a fan grill middle, middle portion, and a fan grill middle, bottom portion;
the fan grill middle, top portion defines a top opening;
the fan grill middle, bottom portion defines a bottom opening;
the fan latch mechanism mounted behind the fan grill middle portion; and
the latch touchpoint is contained within one of the fan grill middle, top portion and the fan grill middle, bottom portion.

7. A fan system for an information handling system comprising:
a fan device; and,
a fan grill component, the fan grill component comprising
a fan grill housing;
a fan grill portion attached to the fan grill housing; and,
a fan carrier latch mechanism mounted to the fan grill housing, the fan carrier latch mechanism being mounted to be positioned in front of a hub portion of a fan device of the fan system.

8. The fan system of claim 7, wherein:
the fan carrier latch mechanism includes a latching portion, the latching portion being configured to removably attach the fan grill component to the fan device.

9. The fan system of claim 8, wherein:
the fan carrier latch mechanism includes a latch touchpoint.

10. The fan system of claim 9, wherein:
the fan carrier latch mechanism includes a top portion, a middle portion and a bottom portion;
the fan latch mechanism is contained within the middle portion; and
the latch touchpoint is contained within one of the top portion and the bottom portion.

11. The fan system of claim 10, wherein:
the fan grill portion includes a middle portion; and,
the fan carrier latch mechanism is mounted behind the middle portion.

12. The fan system of claim 11, wherein:
the middle portion includes a fan grill middle, top portion, a fan grill middle, middle portion, and a fan grill middle, bottom portion;
the fan grill middle, top portion defines a top opening;
the fan grill middle, bottom portion defines a bottom opening;
the fan latch mechanism mounted behind the fan grill middle portion; and
the latch touchpoint is contained within one of the fan grill middle, top portion and the fan grill middle, bottom portion.

13. A system comprising:
a chassis;
a processor contained within the chassis;
a data bus coupled to the processor;
a plurality of components contained within the chassis; and,
a fan system for cooling the plurality of components, the fan system comprising
a fan device; and,
a fan grill component, the fan grill component comprising
a fan grill housing;
a fan grill portion attached to the fan grill housing; and,
a fan carrier latch mechanism mounted to the fan grill housing, the fan carrier latch mechanism being mounted to be positioned in front of a hub portion of a fan device of the fan system.

14. The system of claim 13, wherein:
the fan carrier latch mechanism includes a latching portion, the latching portion being configured to removably attach the fan grill component to the fan device.

15. The system of claim 14, wherein:
the fan carrier latch mechanism includes a latch touchpoint.

16. The system of claim 15, wherein:
the fan carrier latch mechanism includes a top portion, a middle portion and a bottom portion;
the fan latch mechanism is contained within the middle portion; and
the latch touchpoint is contained within one of the top portion and the bottom portion.

17. The system of claim 16, wherein:
the fan grill portion includes a middle portion; and,
the fan carrier latch mechanism is mounted behind the middle portion.

18. The system of claim 17, wherein:
the middle portion includes a fan grill middle, top portion, a fan grill middle, middle portion, and a fan grill middle, bottom portion;
the fan grill middle, top portion defines a top opening;
the fan grill middle, bottom portion defines a bottom opening;
the fan latch mechanism mounted behind the fan grill middle portion; and
the latch touchpoint is contained within one of the fan grill middle, top portion and the fan grill middle, bottom portion.
